(19) United States
(12) Patent Application Publication
(10) Pub. No.: US 2006/0061945 A1
(43) Pub. Date: Mar. 23, 2006

(54) Plasma display module having filtering film and plasma display apparatus including plasma display module

(76) Inventor: Sok-San Kim, Suwon-si (KR)

Correspondence Address: Robert E. Bushnell, Suite 300, 1522 K Street, N.W., Washington, DC, 20005, US

(21) Appl. No.: 11/175,289

(22) Filed: Jul. 7, 2005

(30) Foreign Application Priority Data
Sep. 22, 2004 (KR) 10-2004-0075967

(51) Int. Cl. G06F 1/16; H05K 7/00; H05K 5/00

(52) U.S. Cl. 361/681; 361/688

(57) ABSTRACT

A plasma display module having a filtering film and adapted for use with a plasma display apparatus includes: a Plasma Display Panel (PDP), a chassis base including a front side adapted to be connected to the PDP and a rear side provided with a circuit board for the PDP, and a filtering film arranged on a front side of the PDP.

### CLAIM OF PRIORITY

This application makes reference to, incorporates the same herein, and claims all benefits accruing under 35 U.S.C.§ 119 from an application for PLASMA DISPLAY MODULE HAVING FILTERING FILM AND PLASMA DISPLAY APPARATUS INCLUDING PLASMA DISPLAY MODULE earlier filed in the Korean Intellectual Property Office on the 22 Sep. 2004 and there duly assigned Serial No. 10-2004-0075967.

### BACKGROUND OF THE INVENTION

1. Technical Field

The present invention relates to a plasma display apparatus, and more particularly, to a plasma display module having a filtering film and a plasma display apparatus including the plasma display module.

2. Related Art

A plasma display apparatus includes a front case having a peripheral portion defining a window, an electromagnetic wave shielding filter covering the window, a conductive filter holder which is fixed to coupling bosses of the front case with screws 23 and presses the electromagnetic wave shielding filter against the peripheral portion of the front case, a Plasma Display Panel (PDP) which is disposed at the rear side of the filter holder and includes front and rear panels, a chassis base supporting the PDP, connection cables which are disposed at the rear side of the chassis base and connect the PDP to a circuit unit driving the PDP, and a rear case which is disposed at the rear side of the chassis base and is coupled to the front case. A heat conductive sheet is interposed between the PDP and the chassis base.

In the plasma display apparatus having the above-described configuration, an electromagnetic wave shielding filter is provided for shielding electromagnetic waves generated during the operation of the PDP. A glass filter is generally used as the electromagnetic wave shielding filter. The glass filter is heavy, because it is formed using a glass substrate and covers the whole window. Specifically, the size and thickness of the glass filter increase with the size of the plasma display. Therefore, there are problems in that the glass filter increases in price and weight.

### SUMMARY OF THE INVENTION

The present invention provides a plasma display module including a filtering film which is light and inexpensive.

Furthermore, the present invention provides a plasma display apparatus in which the filtering film can be stably grounded.

According to one aspect of the present invention, a plasma display module is provided comprising: a Plasma Display Panel (PDP); a chassis base including a front side adapted to be connected to the PDP and a rear side provided with a circuit board for the PDP; and a filtering film arranged on a front side of the PDP.

According to another aspect of the present invention, a plasma display apparatus is provided comprising: a front case having a window arranged therein; a rear case adapted to define an inner space together with the front case; a Plasma Display Panel (PDP) arranged in the inner space; a chassis base including a front side adapted to be connected to the PDP and a rear side provided with a circuit board for the PDP; and a filtering film arranged on a front side of the PDP and adapted to cover the window.

The plasma display apparatus preferably further comprises a shielding member interposed between the front case and the filtering film.

The shielding member preferably comprises a conductive material.

The shielding member preferably comprises an elastic member.

The shielding member preferably comprises a sponge EMI.

The front case preferably comprises a conductive material.

The front case preferably comprises a metal.

The plasma display apparatus preferably further comprises a filter holder interposed between the front case and the filtering film.

The filter holder preferably comprises a conductive material.

The plasma display apparatus preferably further comprises a bracket affixed to the rear side of the chassis base and adapted to couple the chassis base to the filter holder.

The bracket preferably comprises a conductive material.

The bracket preferably extends vertically to traverse the chassis base.

The plasma display apparatus preferably further comprises a bracket affixed to a rear side of the chassis base and adapted to couple the chassis base to the front case.

The bracket preferably comprises a conductive material.

The bracket preferably extends vertically to traverse the chassis base.

The front case preferably comprises a plastic.

According to the present invention, the plasma display module becomes light due to the filtering film provided thereto. Furthermore, since the filter holder is not coupled to the front case, the tima and cost required for manufacturing the plasma display apparatus can be reduced. If an additional conductive filter holder is provided, the grounding structure of the plasma display apparatus can be improved.

### BRIEF DESCRIPTION OF THE DRAWINGS

A more complete appreciation of the present invention, and many of the attendant advantages thereof, will be readily apparent as the present invention becomes better understood by reference to the following detailed description when considered in conjunction with the accompanying drawings in which like reference symbols indicate the same or similar components, wherein:

FIG. 1 is a partial sectional view of a plasma display apparatus;

FIG. 2 is an exploded perspective view of a plasma display apparatus according to a first embodiment of the present invention;

FIG. 3 is a partial sectional view taken along Line III-III of FIG. 2;

FIG. 4 is an exploded perspective view of a plasma display apparatus according to a second embodiment of the present invention; and

FIG. 5 is a sectional view taken along Line V-V of FIG. 4.

### DETAILED DESCRIPTION OF THE INVENTION

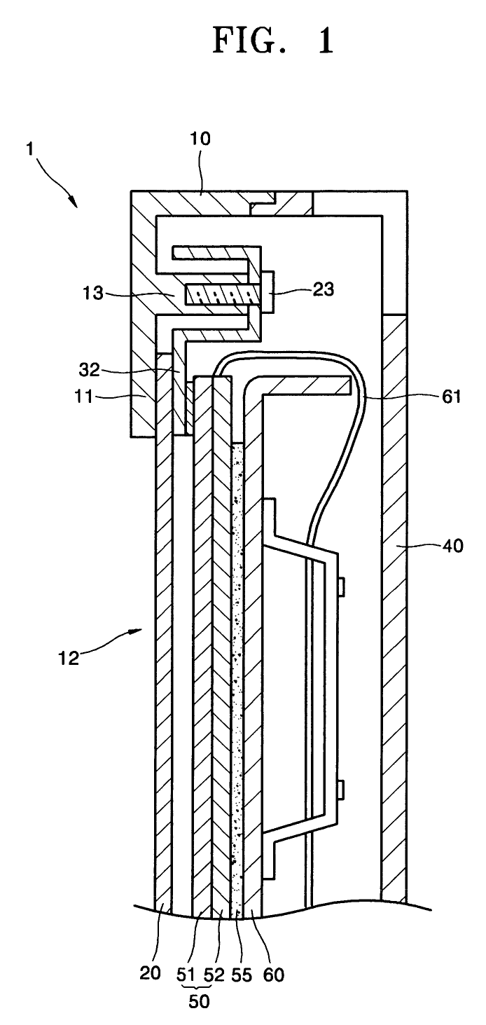

A plasma display apparatus 1, as shown in FIG. 1, includes a front case 10 having a peripheral portion 11 defining a window 12, an electromagnetic wave shielding filter 20 covering the window 12, a conductive filter holder 32 which is fixed to coupling bosses 13 of the front case 10 with screws 23 and presses the electromagnetic wave shielding filter 20 against the peripheral portion 11 of the front case 10, a Plasma Display Panel (PDP) 50 which is disposed at the rear side of the filter holder 32 and includes front and rear panels 51 and 52, a chassis base 60 supporting the PDP 50, connection cables 61 which are disposed at the rear side of the chassis base 60 and connect the PDP 50 to a circuit unit (not shown) driving the PDP 50, and a rear case 40 which is disposed at the rear side of the chassis base 60 and is coupled to the front case 10. A heat conductive sheet 55 is interposed between the PDP 50 and the chassis base 60.

In the plasma display apparatus 1 having the above-described configuration, an electromagnetic wave shielding filter 20 is provided for shielding electromagnetic waves generated during the operation of the PDP 50. A glass filter is generally used as the electromagnetic wave shielding filter 20. The glass filter is heavy, because it is formed using a glass substrate and covers the whole window 12. Specifically, the size and thickness of the glass filter increase with the size of the plasma display. Therefore, there are problems in that the glass filter increases in price and weight.

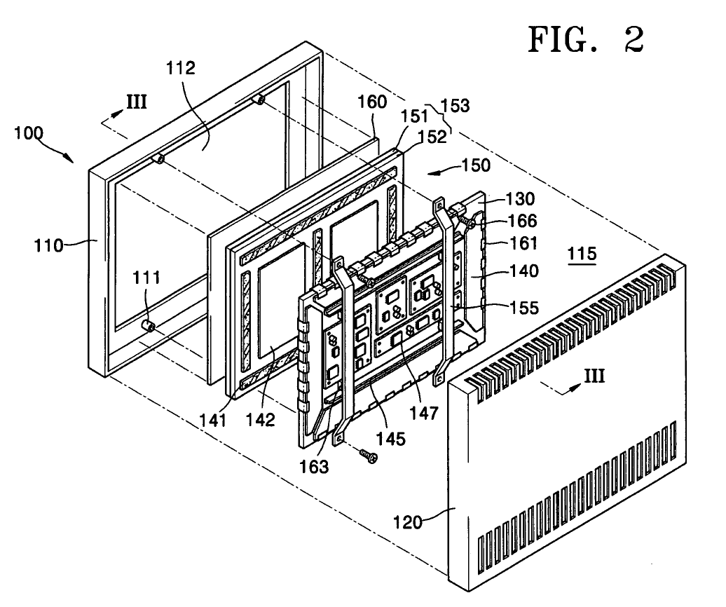

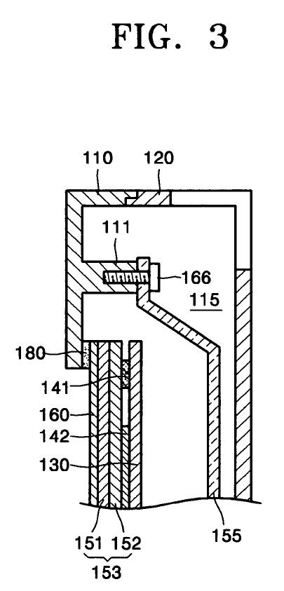

Hereinafter, a plasma display apparatus 100 according to a first embodiment of the present invention is described in detail below with reference to FIGS. 2 and 3.

The plasma display apparatus 100 includes a front case 110 in which a window 112 is formed, a rear case 120 which is coupled to the front case 110 and which defines an inner space 115 together with the front case 110, and a plasma display module 150 disposed inside the inner space 115.

The front case 110 and the rear case 120 are coupled to each other and protect the plasma display module 150 disposed inside the inner space 115. A stand device (not shown) coupled to the plasma display module 150 supports it vertically.

The plasma display module 150 includes a Plasma Display Panel (PDP) 153, a chassis base 130 whose front side is connected to the PDP 153 and whose rear side is provided with boards 140 on which circuits for driving the PDP 153 are wired, and a filtering film 160 which is disposed at a front side of the PDP 153 and which covers the window 112.

The PDP 153 includes a first panel 151 and a second panel 152 coupled to the first panel 151. It is preferable that the first panel 151 be provided with a front substrate, sustain electrodes formed on a bottom surface of the front substrate, a first dielectric layer covering the sustain electrodes, and a protective layer formed on the first dielectric layer, and the second panel 152 be provided with a rear substrate, address electrodes formed on the rear substrate to intersect the sustain electrodes, a second dielectric layer covering the address electrodes, partition walls formed on the second dielectric layer, and fluorescent layers coated inside discharge cells defined by the partition walls. The PDP 153 has a three-electrode surface-discharge PDP structure. However, the present invention is not limited to this structure and can realize images by various methods such as a two-electrode opposed-discharge structure. The structure and the driving method of the PDP 153 are apparent to those of ordinary skill in the art and a description thereof has been omitted for the sake of brevity.

The chassis base 130, which can be made by a casting or pressing method, supports the PDP 153 and the circuit boards 140. It is preferable that the chassis base 130 be made of metal such as aluminum, which has an excellent heat conductivity in order to effectively transfer heat from the PDP 153 to the outside. The PDP 153 and the chassis base 130 are attached to each other by double-sided adhesive tape 141.

Heat conductive sheets 142 having a high heat conductivity are interposed between the PDP 153 and the chassis base 130 and transfer heat generated in the PDP 153 to the chassis base 130. Silicon glass, a silicon heat-radiation sheet, an acryl-based heat radiation and pressure reduction adhesive sheet, a urethane-based heat radiation and pressure reduction adhesive sheet or the like can be used for the heat conductive sheet 142.

As the plasma display becomes large in size, the chassis also becomes large in size. The increasing size of the chassis base increases the possibility that the chassis base will buckle due to an increased external load applied thereto, and this reduces structural safety. Furthermore, since a temperature of the chassis base rises during the time of operating the PDP, the chassis base is heat-expanded and thus bends toward the front or rear side. When the chassis base is bent, the PDP cannot be safely supported, and the chassis base and the PDP become unfastened. As a result, the heat generated in the PDP cannot be effectively transferred to the chassis base. To overcome such a problem, a plurality of reinforcing members 145 are disposed at a rear side of the chassis base 130. The reinforcing members 145 have a cross-section of various shapes and have an elongated shape in one direction.

Brackets 155 are disposed at a rear side of the chassis base 130 to vertically traverse it. Supporting members 163 are disposed between the brackets 155 and the chassis base 130 and fix the brackets 155 to the chassis base 130. Each of the brackets 155 vertically extends parallel to the chassis base 130 at the rear side of the chassis base 130, and is bent at upper and lower edges of the chassis base 130. Then, upper and lower ends of the brackets 155 are fixed to the front case 110 with screws 166. The brackets 155 are made of a strong material, such as aluminum and steel, and are coupled to coupling bosses of the front case 110, and thereby perform a function of fixing the plasma display module 150 and both the cases 110 and 120. Furthermore, when the brackets 155 are made of an electrically conductive material, the brackets 155 perform a function of electrically connecting the front case 110 to the chassis base 130 and serve as a grounding unit.

The circuit boards 140 for driving the PDP 153 are disposed at the rear side of the chassis base 130. Devices 147 for driving the PDP 153 are disposed at the circuit boards 140. The devices 147 include, but are not limited to, a device for supplying power to the PDP 153 and a device for supplying signals for realizing images to the PDP 153. The circuit board 140 is electrically connected to the PDP 153 via connection cables 161, such as a tape carrier package.

As will be apparently understood by comparing FIGS. 1 and 2, the plasma display apparatus 100 according to the first embodiment of the present invention is not provided with a glass filter 20 and a filter holder 32 pressing the glass filter 20 against a peripheral portion 11 of a front case 10. When the PDP 153 operates, electromagnetic waves are generated. These electromagnetic waves are harmful to the human body and can cause a malfunction of electronic apparatus adjacent thereto. Thus, there is a need to reduce the electromagnetic waves radiated to the outside of the plasma display apparatus 100. The plasma display apparatus 100 includes the filtering film 160 for reducing the electromagnetic waves radiated to the outside. The filtering film 160 is disposed at a front surface of the PDP 153 and is made of a thin film. The filtering film 160 performs various functions in addition to a function of shielding electromagnetic waves by forming the filtering film 160 in a multi-layer structure. The function of the glass filter can be effectively performed by selectively forming an electromagnetic wave shielding layer, a planarizing flat layer, a near-infrared ray shielding layer, a scattered-reflection-shielding layer, etc., between base films made of a TriAcetylCelluose (TAC) group, a Poly Ethylene Terephthalate (PET) group, a Poly Butylene Terephthalate (PBT) group, a Poly Ethylene Naphthalate (PEN) group, or the like.

The electromagnetic wave shielding layer (not shown) can be formed by a conductive material so that at least a central portion opposite to the window 112 is formed in the shape of mesh. A conductive layer (for example, a metal layer of copper, or silver, etc.) having a predetermined thickness is formed on a base film, and then the central portion thereof is etched with a predetermined pattern (for example, in the shape of mesh), whereby the electromagnetic wave shielding layer is formed. A pitch of the mesh and the width of lines forming the mesh can be changed according to a pattern of a resist layer used during etching. The electromagnetic wave shielding layer can be obtained by forming a transparent layer by applying a transparent conductive material to the entire surface of the base film.

The electromagnetic wave shielding layer is connected to the conductive front case 110 and is grounded. The front case 110 is generally made of material including a conductive metal such as aluminum. The front case 110 can be made of conductive plastic which is formed by mixing metal powders or fine metal fibers with plastic injection material and then by injecting the resultant mixture. Furthermore, it is preferable for the rear case 120 to be made of the same material as that of the front case 110. At least one of the front and rear cases 110 and 120 are made of a conductive material in order to secure a ground. Accordingly, the front case 110 can be made of a non-conductive material.

As shown in FIG. 3, a shielding member 180 can be interposed between the electromagnetic wave shielding layer attached to the filtering film 160 and the front case 110. The shielding member 180 is disposed along a portion in which the filtering film 160 and the front case 110 are opposite to each other. The shielding member 180 electrically connects the filtering film 160 and the front case 110 due to its excellent conductivity, in addition to performing a function of preventing an alien substance from infiltrating into an inner space through the window 112. Specifically, it is preferable that the shielding member 180 be made of an elastic material for preventing the PDP 153 being damaged due to a pressure applied between the PDP 153 and the front case 110. In the present embodiment, the shielding member 180 is made of a sponge EMI. The sponge EMI is excellent in conductivity and elasticity, since the inside thereof is made of a sponge and the outside thereof is coated with conductive material.

Electromagnetic energy captured by the electromagnetic wave shielding layer of the filtering film 160 is transferred to the front case 110, the chassis base 130, etc. via the shielding member 180, or is radiated outside of the plasma display apparatus 100.

It is preferable that the filtering film 160 include a planarizing layer covering the electromagnetic wave shielding layer. Since the central portion of the electromagnetic wave shielding layer has a mesh shape, the mesh can interfere with light emitted from fluorescent layers provided to the PDP 153. The planarizing layer performs a function of minimizing the light interference caused by the mesh and prevents the electromagnetic wave shielding layer from being damaged during a manufacturing process.

Furthermore, it is preferable that the filtering film 160 include a near infrared ray shielding layer. A discharge gas contained within the PDP 153 generally includes Xe, and Xe emits near infrared rays during discharging. These near infrared rays are harmful to the human body and can cause a malfunction of electronic apparatus adjacent thereto. Therefore, it is preferable to shield the near infrared rays. The near infrared ray shielding layer includes a component which absorbs the near infrared rays. Furthermore, the filtering film 160 can further include a scattered reflection shielding layer for preventing the scattered reflection on the near infrared shielding layer from being generated. The layer attached to the filtering film 160 and the positional arrangement thereof are not limited to the above descriptions.

The filtering film 160 is attached to a front surface of the PDP 153 by an acryl-based adhesive, etc.

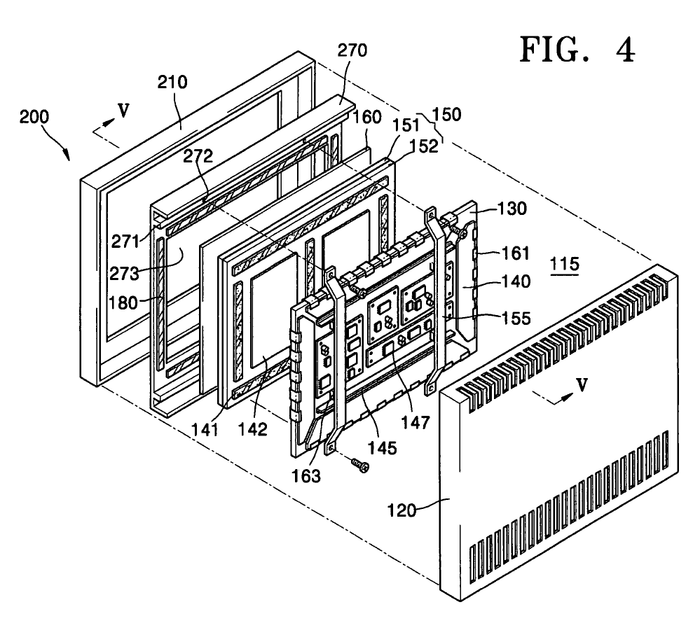

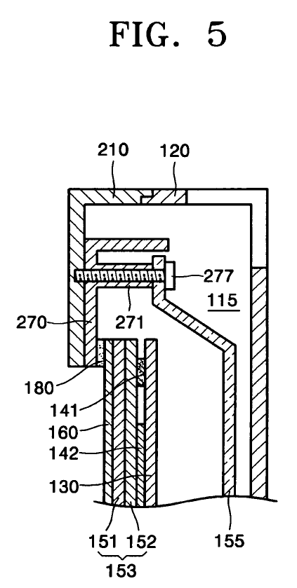

Hereinafter, a second embodiment of the present invention is described below with respect to portions different from those of the first embodiment with reference to FIGS. 4 and 5. The same elements as shown in FIGS. 2 and 3 are denoted by the same reference numerals. The second embodiment is different from the first embodiment in that an additional filter holder 270 is provided. The filter holder 270 is interposed between the shielding member 180 and a front case 210. A window 273 is formed in a central portion of the filter holder 270 similarly to the front case 210, and the shielding member 180 is disposed at an inner side of a portion in which the window 273 is formed. The filter holder 270 is provided with flat portions 271 which are disposed at upper and lower edge portions and which extend in a horizontal direction. Through-holes 272 are formed in the flat portions 271. The brackets 155 are fixed to the filter holder 270 by screws 277. It is preferable that the filter holder 270 be made of a conductive material for performing a function of grounding after being electrically connected to the electromagnetic wave shielding layer provided to the filtering film 160 via the shielding member 180. Specifically, when the front case 210 is made of a plastic injection material instead of a conductive material, the conductive filter holder 270 performs an important function of grounding. It is also possible to electrically isolate the conductive members by interposing a non-conductive member therebetween.

The structure and the operation of the plasma display module 150 including the filtering film 160, the PDP 153, the chassis base 130, and the circuit board 140 are same as those of the first embodiment, and thus a description thereof has been omitted.

According to the plasma display module and the plasma display apparatus employing the plasma display module, it is possible to provide a plasma display module and a plasma display apparatus employing the plasma display module in which weight is reduced and a stable ground is possible.

While the present invention has been particularly shown and described with reference to exemplary embodiments thereof, it will be understood by those of ordinary skill in the art that various modifications in form and detail can be made therein without departing from the spirit and scope of the present invention as defined by the following claims.

What is claimed is:

1. A plasma display module, comprising:
a Plasma Display Panel (PDP);
a chassis base including a front side adapted to be connected to the PDP and a rear side provided with a circuit board for the PDP; and
a filtering film arranged on a front side of the PDP.

2. A plasma display apparatus, comprising:
a front case having a window arranged therein;
a rear case adapted to define an inner space together with the front case;
a Plasma Display Panel (PDP) arranged in the inner space;
a chassis base including a front side adapted to be connected to the PDP and a rear side provided with a circuit board for the PDP; and
a filtering film arranged on a front side of the PDP and adapted to cover the window.

3. The plasma display apparatus according to claim 2, further comprising a shielding member interposed between the front case and the filtering film.

4. The plasma display apparatus according to claim 3, wherein the shielding member comprises a conductive material.

5. The plasma display apparatus according to claim 3, wherein the shielding member comprises an elastic member.

6. The plasma display apparatus according to claim 3, wherein the shielding member comprises a sponge EMI.

7. The plasma display apparatus according to claim 2, wherein the front case comprises a conductive material.

8. The plasma display apparatus according to claim 7, wherein the front case comprises a metal.

9. The plasma display apparatus according to claim 2, further comprising a filter holder interposed between the front case and the filtering film.

10. The plasma display apparatus according to claim 9, wherein the filter holder comprises a conductive material.

11. The plasma display apparatus according to claim 9, further comprising a bracket affixed to the rear side of the chassis base and adapted to couple the chassis base to the filter holder.

12. The plasma display apparatus according to claim 11, wherein the bracket comprises a conductive material.

13. The plasma display apparatus according to claim 11, wherein the bracket extends vertically to traverse the chassis base.

14. The plasma display apparatus according to claim 2, further comprising a bracket affixed to a rear side of the chassis base and adapted to couple the chassis base to the front case.

15. The plasma display apparatus according to claim 14, wherein the bracket comprises a conductive material.

16. The plasma display apparatus according to claim 14, wherein the bracket extends vertically to traverse the chassis base.

17. The plasma display apparatus according to claim 2, wherein the front case comprises a plastic.
